(19) United States
(12) Patent Application Publication
(10) Pub. No.: US 2025/0105823 A1
(43) Pub. Date: Mar. 27, 2025

(54) HYBRID MODIFIED LATTICE FILTER

(71) Applicant: SKYWORKS GLOBAL PTE. LTD., Singapore (SG)

(72) Inventors: Zhiyuan Ni, Irvine, CA (US); Li Chen, Irvine, CA (US); Stephane Richard Marie Wloczysiak, Irvine, CA (US); Kwang Jae Shin, Yongin (KR); Jae Hyung Lee, Seoul (KR); Joshua James Caron, Summerfield, NC (US)

(21) Appl. No.: 18/889,796

(22) Filed: Sep. 19, 2024

Related U.S. Application Data
(60) Provisional application No. 63/539,938, filed on Sep. 22, 2023.

(51) Int. Cl. H03H 9/56

(52) U.S. Cl. CPC H03H 9/568

(57) ABSTRACT

A circuit comprising a first output, a second output, an input, a lattice filter stage, and a ladder filter stage. The ladder filter stage is coupled to the input and to the lattice filter stage, the lattice filter stage including at least one resonator coupled to the first output and to the ladder filter stage, at least one resonator coupled to the second output and to the ladder filter stage, the ladder stage including at least one resonator coupled to the input and at least one resonator coupled to a common connection.

### CROSS-REFERENCE TO RELATED APPLICATIONS

The present application claims priority under 35 U.S.C. § 119 (e) to U.S. Provisional Application No. 63/539,938 titled HYBRID MODIFIED LATTICE FILTER, filed Sep. 22, 2023, which is hereby incorporated by reference in its entirety for all purposes.

### BACKGROUND

### 1. Field of the Disclosure

At least one example in accordance with the present disclosure relates generally to filtering telecommunication signals.

### 2. Discussion of Related Art

Communication devices may use filters and filtering systems to clarify and control the content of signals received and transmitted by telecommunication systems.

### SUMMARY

According to at least one aspect of the present disclosure, a circuit is provided comprising a first output, a second output, an input, a lattice filter stage, and a ladder filter stage coupled to the input and to the lattice filter stage. The lattice filter stage includes a first resonator coupled to the first output and to the ladder filter stage, and a second resonator coupled to the second output and to the ladder filter stage. The ladder stage includes a third resonator coupled to the input and a fourth resonator coupled to a ground connection.

In one example, the lattice filter stage further incudes a fifth resonator coupled between the first output and the ground connection and a sixth resonator coupled between the second output and the third resonator. In a further example, the ladder filter stage further includes a seventh resonator coupled between the first resonator and the third resonator, an eighth resonator coupled between the first and seventh resonators and the ground connection, and wherein the fourth resonator is coupled between the seventh and third resonators and the ground connection.

In a still further example, each of the fourth and eighth resonators is coupled to the ground connection through a respective inductor.

In some examples, the ladder filter stage further includes first and second inductors coupled in parallel with the seventh and third resonators, respectively.

In other examples, the input is coupled to an antenna and to a first port via a matching impedance.

In still further examples, the first output is coupled to a first differential input port of a low noise amplifier and the second output is coupled to a second differential input of the low noise amplifier.

According to another aspect of the present disclosure, a circuit is provided comprising a first output, a second output, an input, a first lattice filter stage, and a second lattice filter stage. The first lattice filter stage includes a first resonator coupled to the first output, a capacitor coupled to the first output, and a second resonator coupled to the second output. The second lattice filter stage includes a third resonator coupled to the input.

In one example, the first lattice filter further includes a fourth resonator coupled between the second output and the third resonator. In a further example, the second lattice filter further includes a fifth resonator coupled between the first and third resonators and a ground connection and a sixth resonator coupled between the second resonator and the input. In a still further example, the second lattice filter further includes a seventh resonator coupled between the second resonator and the ground connection. In yet a further example, the second lattice filter further includes a first inductor coupled between the input and the ground connection. In another example, the circuit further comprises a second inductor coupled between the first and third resonators and the second and seventh resonators, and a third inductor coupled between the first and second outputs. In one example, the circuit further comprises a fourth inductor coupled in parallel with the seventh resonator. In a further example, the circuit further comprises a balun, wherein the balun includes the third inductor, a fourth inductor and a core, a first terminal of the fourth inductor being coupled to a single input low noise amplifier and a second terminal of the fourth inductor being coupled to the ground connection.

In another example, the input is coupled to an antenna and to a first port via a matching impedance.

In yet another example, the first output is configured to be coupled to a first differential input port of a low noise amplifier and wherein the second output is configured to be coupled to a second differential input of the low noise amplifier.

In yet another aspect of the present disclosure, a circuit is provided. The circuit comprises a first output, a second output, an input, a first lattice filter stage coupled to the first input and including a first resonator, and a second lattice filter stage coupled to the second input and including a second resonator. The circuit further comprises a first coil coupled to the first lattice filter stage, a second coil coupled to the second lattice filter stage, and a third coil coupled to the output and electromagnetically coupled to at least one of the first coil or the second coil.

In one example, the first output is configured to be coupled to a first differential input of a low noise amplifier and the second output is configured to be coupled to a second differential input of the low noise amplifier.

In another example, the input is configured to be coupled to an antenna.

### BRIEF DESCRIPTION OF THE DRAWINGS

Various aspects of at least one embodiment are discussed below with reference to the accompanying figures, which are not intended to be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or nearly identical component that is illustrated in various figures is represented by a like numeral. For purposes of clarity, not every component may be labeled in every figure. In the figures:

FIG. 1 illustrates a hybrid ladder and lattice filter topology according to an example;

FIG. 2 illustrates a lattice filter topology according to an example;

FIG. 3 illustrates a double lattice filter topology according to an example;

FIG. 4 illustrates a hybrid lattice filter topology according to an example;

FIG. 5 illustrates a differential lattice-ladder hybrid filter topology according to an example;

FIG. 6 illustrates a differential lattice filter topology according to an example;

FIG. 7 illustrates a differential lattice-ladder hybrid filter topology according to an example;

FIG. 8 illustrates a differential lattice-ladder hybrid filter topology according to an example;

FIG. 9 illustrates a modified dual lattice filter topology according to an example;

FIG. 10 illustrates a modified differential dual lattice filter topology according to an example;

FIG. 11A illustrates a ladder filter topology according to an example;

FIG. 11B illustrates a lattice filter according to an example;

FIG. 12 illustrates a balun transformer according to an example; and

FIG. 13 illustrates an example of a cross-connection according to an example.

### DETAILED DESCRIPTION

Examples of the methods and systems discussed herein are not limited in application to the details of construction and the arrangement of components set forth in the following description or illustrated in the accompanying drawings. The methods and systems are capable of implementation in other embodiments and of being practiced or of being carried out in various ways. Examples of specific implementations are provided herein for illustrative purposes only and are not intended to be limiting. In particular, acts, components, elements and features discussed in connection with any one or more examples are not intended to be excluded from a similar role in any other examples.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items.

References to “or” may be construed as inclusive so that any terms described using “or” may indicate any of a single, more than one, and all of the described terms. In addition, in the event of inconsistent usages of terms between this document and documents incorporated herein by reference, the term usage in the incorporated features is supplementary to that of this document; for irreconcilable differences, the term usage in this document controls.

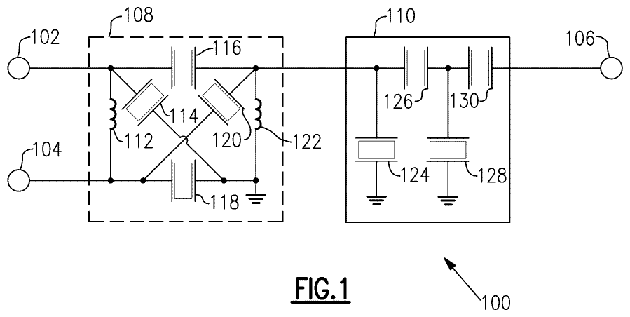

Modern mobile networks, such as 5th generation (5G) and later, may use sub-6 GHZ front-end modules (FEMs) to facilitate transmitting and receiving signals. Sub-6 GHZ bands may be particularly wide bands, and may have stringent intermodulation distortion requirements. For example, for the n77 frequency band, FEMs and telecommunication devices may require pass band filters that have a fractional bandwidth of approximately 24-25% and out of band rejection of 50 dB or more. Traditional acoustic filters, due to electromechanical coupling coefficient (“kt2”) limits of the resonators they use, cannot support high rejection at the desired frequencies while still having a desired passband response. Lumped element filters may be able to meet the rejection requirement, but will tend to suffer from high insertion loss. Some of the filters provided herein may meet the requirements (e.g., fractional bandwidth and/or out of band rejection) while having low insertion loss, making these filters ideal for use in sub-6 GHZ bands. FIG. 1 illustrates a hybrid ladder and lattice filter topology 100 (“hybrid topology 100”) according to an example. The hybrid topology 100 may be particularly well-suited to improving common mode rejection.

The hybrid topology 100 includes a first node 102, a second node 104, a third node 106, a lattice filter stage 108, a ladder filter stage 110, a first inductor 112, a first resonator 114, a second resonator 116, a third resonator 118, a fourth resonator 120, a second inductor 122, a fifth resonator 124, a sixth resonator 126, a seventh resonator 128, and an eighth resonator 130. The lattice filter stage 108 includes at least the first inductor 112, second inductor 122, first resonator 114, second resonator 116, third resonator 118, and fourth resonator 120. The ladder filter stage 110 includes at least the fifth resonator 124, the sixth resonator 126, the seventh resonator 128, and the eighth resonator 130.

The first node 102 is coupled at a first connection to the first inductor 112, first resonator 114, and second resonator 116. The first inductor 112 is coupled at a first connection to the first node 102, the first resonator 114, and the second resonator 116, and at a second connection to the second node 104, the third resonator 118, and the fourth resonator 120. The second node 104 is coupled at a first connection to the first inductor 112, the third resonator 118, and the fourth resonator 120. The second inductor 122 is coupled at a first connection to the first resonator 114, third resonator 118, and a ground, neutral, and/or equipotential node (hereafter “equipotential node”). The second inductor 122 is further coupled at a second connection to the second resonator 116 and fourth resonator 120, as well as to the fifth resonator 124 and sixth resonator 126. The fifth resonator 124 is coupled to the equipotential node at a first connection and to the second resonator 116, fourth resonator 120, second inductor 122, and sixth resonator 126 at a second connection. The sixth resonator 126 is coupled to the second resonator 116, fourth resonator 120, second inductor 122, and fifth resonator 124 at a first connection, and to the seventh resonator 128 and eighth resonator 130 at a second connection. The seventh resonator 128 is coupled to the equipotential node at a first connection and to the sixth resonator 126 and eighth resonator 130 at a second connection. The eighth resonator 130 is coupled to the sixth resonator 126 and seventh resonator 128 at a first connection and to the third node 106 at a second connection.

The first node 102 may be configured to receive or send radio frequency (RF) signals. For example, the first node 102 may be an RF output for a given polarity (e.g., positive or negative) of an RF signal.

The second node 104 may be configured to send or receive RF signals. For example, the second node 104 may be an RF output for a given polarity (e.g., negative or positive) of an RF signal, and may be for the polarity of an RF signal opposite the polarity present at the first node 102.

The third node 106 may be configured to send or receive RF signals. For example, the third node 106 may be an RF input for an RF signal.

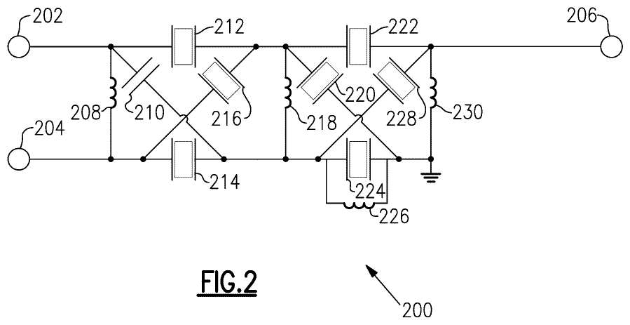

FIG. 2 illustrates a lattice filter topology 200 (“lattice topology 200”) according to an example. The lattice topology 200 effectively includes two lattice filters that are combined into a single filter stage, and may use capacitors to replace resonators.

The lattice topology 200 includes a first node 202, a second node 204, a third node 206, a first inductor 208, a capacitor 210, a first resonator 212, a second resonator 214, a third resonator 216, a second inductor 218, a fourth resonator 220, a fifth resonator 222, a sixth resonator 224, a third inductor 226, a seventh resonator 228, and a fourth inductor 230.

The first node 202 is coupled to the first inductor 208, the capacitor 210, and the first resonator 212. The second node 204 is coupled to the first inductor 208, second resonator 214, and third resonator 216. The first inductor 208 is coupled at a first connection to the first node 202, the capacitor 210, and the first resonator 212, and at a second connection to the second node 204, second resonator 214, and third resonator 216. The second inductor 218 is coupled at a first connection to the first resonator 212, the third resonator 216, the fourth resonator 220, and the fifth resonator 222, and at a second connection to the capacitor 210, the second resonator 214, the sixth resonator 224, the third inductor 226, and the seventh resonator 228. The fourth inductor 230 is coupled at a first connection to the third node 206, the fifth resonator 222, the seventh resonator 228, and at a second connection to an equipotential node, the fourth resonator 220, the sixth resonator 224, and the third inductor 226.

The first node 202 may be configured to receive or send radio frequency (RF) signals. For example, the first node 202 may be an RF output for a given polarity (e.g., positive or negative) of an RF signal.

The second node 204 may be configured to send or receive RF signals. For example, the second node 204 may be an RF output for a given polarity (e.g., negative or positive) of an RF signal, and may be for the polarity of an RF signal opposite the polarity present at the first node 202.

The third node 206 may be configured to send or receive RF signals. For example, the third node 206 may be an RF input for an RF signal.

In some examples, any or all of the first resonator 212, second resonator 214, third resonator 216, fourth resonator 220, fifth resonator 222, sixth resonator 224, and/or seventh resonator 228 may be replaced with capacitors.

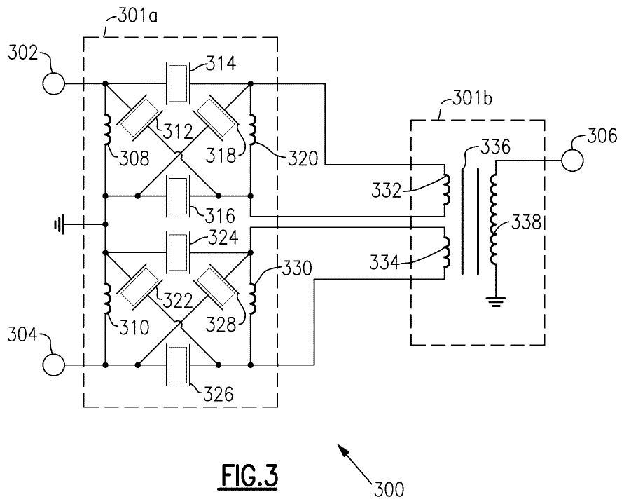

FIG. 3 illustrates a double lattice filter topology 300 (“double lattice topology 300”) according to an example. The double lattice topology 300 may be particularly suited for balanced signals, differential operation modes, and improved common mode rejection.

The double lattice topology 300 includes a first node 302, a second node 304, a third node 306, a first inductor 308, a second inductor 310, a first resonator 312, a second resonator 314, a third resonator 316, a fourth resonator 318, a third inductor 320, a fifth resonator 322, a sixth resonator 324, a seventh resonator 326, an eighth resonator 328, a fourth inductor 330, a fifth inductor 332, a sixth inductor 334, a core 336, and a seventh inductor 338. A lattice filter stage 301a includes at least the first through fourth inductors 308, 310, 320, 330, and the first through eighth resonators 312-318, 322-328. A balun stage 301b includes at least the fifth through seventh inductors 332, 334, 338 and the core 336.

The first node 302 is coupled to the first inductor 308, the first resonator 312, the second resonator 314. The first inductor 308 is coupled at a first connection to the first node 302, the first resonator 312, and the second resonator 314, and at a second connection to the third resonator 316, fourth resonator 318, equipotential node, second inductor 310, fifth resonator 322, and sixth resonator 324. The second node 304 is coupled to the second inductor 310, the seventh resonator 326, and the eighth resonator 328. The second inductor 310 is coupled at a first connection to the equipotential node, first inductor 308, third resonator 316, fourth resonator 318, fifth resonator 322, and sixth resonator 324, and at a second connection to the second node 304, seventh resonator 326, and eighth resonator 328. The third inductor 320 is coupled at a first connection to the second resonator 314, the fourth resonator 318, and the fifth inductor 332, and at a second connection to the first resonator 312, the third resonator 316, and the fifth inductor 332. The fourth inductor 330 is coupled at a first connection to the sixth resonator 324, eighth resonator 328, and sixth inductor 334, and at a second connection to the fifth resonator 322, seventh resonator 326, and sixth inductor 334. The fifth inductor 332 is coupled at a first connection to the second resonator 314, fourth resonator 318, and third inductor 320, and at a second connection to the first resonator 312, third resonator 316, and third inductor 320. The sixth inductor 334 is coupled at a first connection to the sixth resonator 324, eighth resonator 328, and fourth inductor 330, and at a second connection to the fourth inductor 330, fifth resonator 322, and seventh resonator 326. The seventh inductor 338 is coupled to the third node 306 at a first connection and to the equipotential node at a second connection. The fifth inductor 332, sixth inductor 334, and seventh inductor 338 are also electromagnetically linked together and may also be electromagnetically linked to the core 336.

The first node 302 may be configured to receive or send radio frequency (RF) signals. For example, the first node 302 may be an RF output for a given polarity (e.g., positive or negative) of an RF signal.

The second node 304 may be configured to send or receive RF signals. For example, the second node 304 may be an RF output for a given polarity (e.g., negative or positive) of an RF signal, and may be for the polarity of an RF signal opposite the polarity present at the first node 302.

The third node 306 may be configured to send or receive RF signals. For example, the third node 306 may be an RF input for an RF signal.

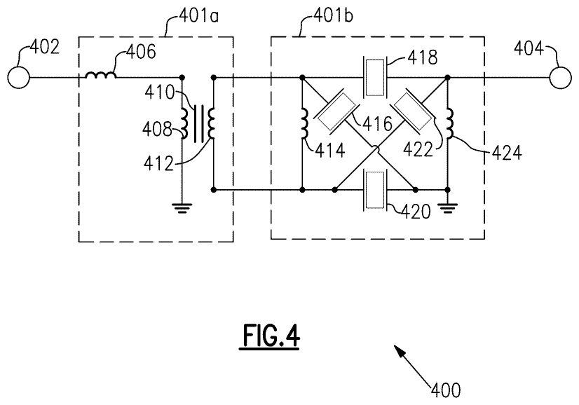

FIG. 4 illustrates a single-ended single-ended (SE-SE) hybrid lattice filter topology 400 (“SE topology 400”) according to an example. The SE topology 400 may be particularly well-suited to single-ended applications.

The SE topology 400 includes a balun stage 401a, a lattice stage 401b, a first node 402, a second node 404, a first inductor 406, a second inductor 408, a core 410, a third inductor 412, a fourth inductor 414, a first resonator 416, a second resonator 418, a third resonator 420, a fourth resonator 422, and a fifth inductor 424. The balun stage 401a may include the first inductor 406, the second inductor 408, the core 410, and the third inductor 412. The lattice stage 401b may include the fourth inductor 414, the fifth inductor 424, the first resonator 416, the second resonator 418, the third resonator 420, and the fourth resonator 422.

The first node 402 is coupled to the first inductor 406. The first inductor 406 is coupled at a first connection to the first node 402, and at a second connection to the second inductor 408. The second inductor 408 is coupled at a first connection to the first inductor 406 and at a second connection to an equipotential node. The third inductor 412 is coupled at a first connection to the fourth inductor 414, the first resonator 416, and the second resonator 418, and at a second connection to the fourth inductor 414, third resonator 420, and fourth resonator 422. The fourth inductor 414 is coupled at a first connection to the third inductor 412, the first resonator 416, and the second resonator 418, and at a second connection to the third inductor 412, third resonator 420, and fourth resonator 422. The fifth inductor 424 is coupled at a first connection to the second resonator 418, fourth resonator 422, and second node 404, and at a second connection to the first resonator 416, third resonator 420, and an equipotential node. The second node 404 is coupled to the second resonator 418, fourth resonator 422, and fifth inductor 424.

The first node 402 may be configured to receive or send radio frequency (RF) signals. For example, the first node 402 may be an RF output for an RF signal.

The second node 404 may be configured to send or receive RF signals. For example, the second node 404 may be an RF input for an RF signal.

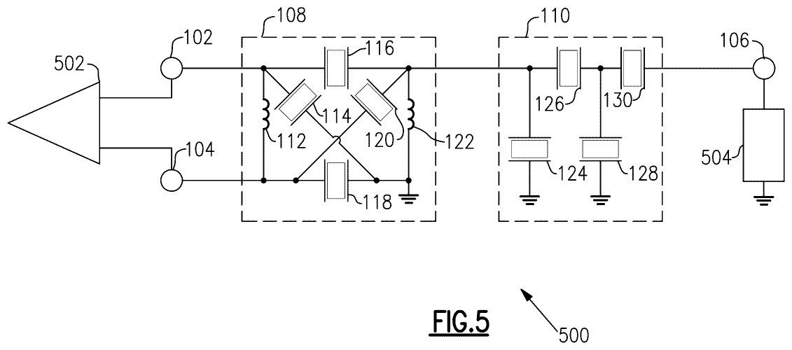

FIG. 5 illustrates a single-ended to differential lattice-ladder hybrid filter 500 (“filter 500”) with a low noise amplifier (LNA) according to an example.

The filter 500 includes the hybrid topology 100 of FIG. 1 and adds an amplifier 502 and an antenna 504. The amplifier 502 may be coupled at a first connection to the first node 102 and at a second connection to the second node 104. An antenna port 504 may be coupled to the third node 106 at a first connection and to an equipotential node at a second connection.

The filter 500 may provide common mode rejection of approximately 25 dB or more. The amplifier 502 may be a differential LNA amplifier. The amplifier 502 has an output that may be configured to provide a voltage for use by other circuit elements or circuits. This implementation does not require a balun, and thus can occupy less space as well as avoid any losses due to the balun.

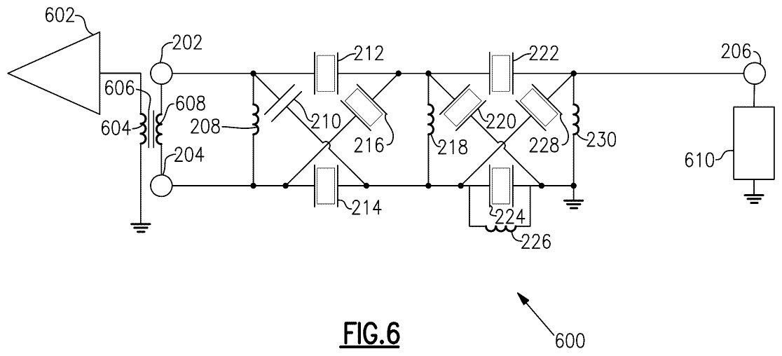

FIG. 6 illustrates a single-ended to differential lattice filter 600 (“filter 600”) with a balun and LNA according to an example.

The filter 600 includes the lattice topology 200 of FIG. 2 and adds an amplifier 602, first balun inductor 604, core 606, second balun inductor 608, and an antenna port 610.

The amplifier 602 is coupled at a first connection to the first balun inductor 604. The first balun inductor 604 is coupled at a first connection to the amplifier 602 and to an equipotential node at a second connection. The second balun inductor 608 is coupled at a first connection to the first node 202 and at a second connection to the second node 204. The first balun inductor 604, core 606, and second balun inductor 608 may be electromagnetically linked. The antenna 610 is coupled to the third node 206 at a first connection, and to an equipotential node at a second connection.

The amplifier 602 may be a single-ended LNA and may have an output configured to provide a voltage to other circuit elements or circuits. In the topology shown in FIG. 6, and including the balun and LNA, the circuit operates as a single-ended to single-ended filter.

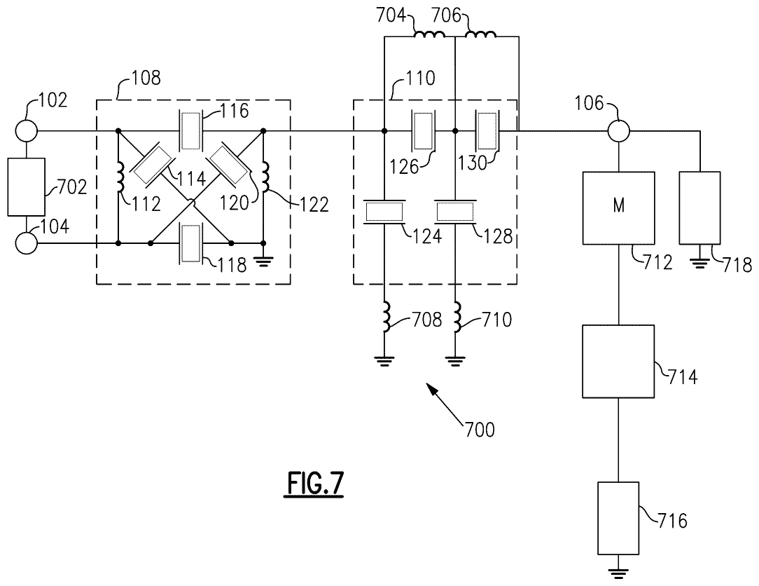

FIG. 7 illustrates a differential lattice-ladder hybrid filter 700 (“filter 700”) according to an example.

The filter 700 includes the hybrid topology 100 of FIG. 1 and adds a first differential port 702, a first ladder inductor 704, a second ladder inductor 706, a third ladder inductor 708, a fourth ladder inductor 710, an impedance matching network 712, a switching device 714 (such as a single-throw-multipole switch), a second single-ended port716, and a third antenna port 718.

The first differential port702 is coupled to the first node 102 at a first connection and to the second node 104 at a second connection. The first ladder inductor 704 is coupled to the second resonator 116, fourth resonator 120, second inductor 122, fifth resonator 124 and sixth resonator 126 at a first connection, and to the second ladder inductor 706, sixth resonator 126, seventh resonator 128, and eighth resonator 130 at a second connection. The second ladder inductor 706 is coupled at a first connection to the first ladder inductor 704, sixth resonator 126, seventh resonator 128, and eighth resonator 130, and at a second connection to the third node 106 and the eighth resonator 130. The third ladder inductor 708 is coupled to the fifth resonator 124 at a first connection and an equipotential node at a second connection. The fourth ladder inductor 710 is coupled to the seventh resonator 128 at a first connection and to an equipotential node at a second connection. The impedance matching network 712 is coupled to the third node 106 at a first connection and to the switching device 714 at a second connection. The switching device 714 is coupled to the impedance matching network 712 at a first connection and to the second single-ended port 716 at a second connection. The second single-ended port 716 is coupled to the switching device 714 at a first connection and to an equipotential node at a second connection. The third antenna port 718 is coupled to the third node 106 at a first connection and to an equipotential node at a second connection. The first differential port 702 may have an impedance of approximately 70 Ohms, the second single-ended port 716 may have an impedance of approximately 50 Ohms, and the antenna port 718 may have an impedance of approximately 60 Ohms at frequencies within the n77 band. In the configuration shown in FIG. 7, the filter 700 acts as a single-ended to differential hybrid lattice-ladder filter operating in a differential mode.

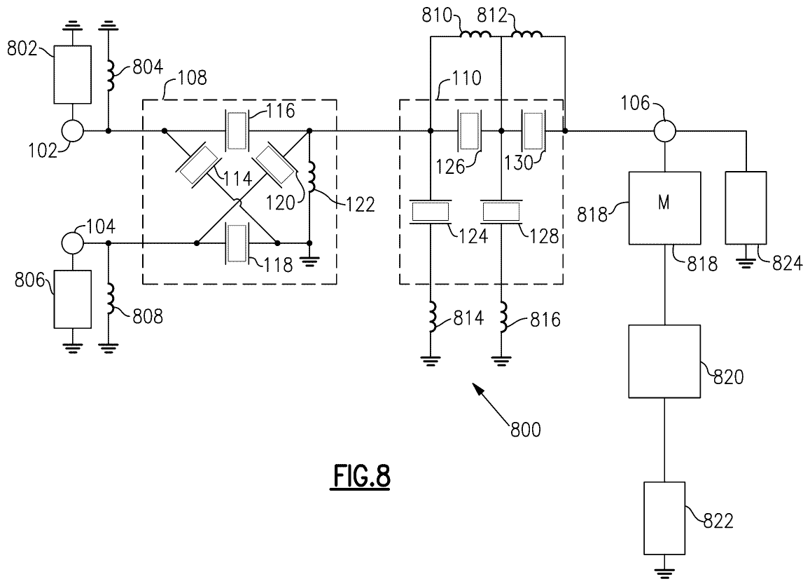

FIG. 8 illustrates a differential lattice-ladder hybrid filter 800 (“differential hybrid filter 800”) according to an example. The differential hybrid filter 800 includes the hybrid topology 100 of FIG. 1, however the first inductor 112 has been removed and various other components added.

The differential hybrid filter 800 includes a first differential port 802, a first differential inductor 804, a second differential port 806, a second differential inductor 808, a first ladder inductor 810, a second ladder inductor 812, a third ladder inductor 814, a fourth ladder inductor 816, an impedance matching network 818, a switching device 820, a third single-ended port822, and a fourth antenna port 814.

The first differential port 802 is coupled at a first connection to an equipotential node and at a second connection to the first node 102. The first differential inductor 804 is coupled to an equipotential node at a first connection and to the first node 102 at a second connection. The first resonator 114 and second resonator 116 are coupled to the first node 102 at a first connection as well. The second differential port 806 is coupled to an equipotential node at a first connection and to the second node 104 at a second connection. The second differential inductor 808 is coupled to an equipotential node at a first connection and to the second node 104 at a second connection. The third resonator 118 and fourth resonator 120 are coupled at a first connection to the second node 104. The first ladder inductor 810 is coupled to the second resonator 116, fourth resonator 120, second inductor 122, fifth resonator 124 and sixth resonator 126 at a first connection, and to the second ladder inductor 812, sixth resonator 126, seventh resonator 128, and eighth resonator 130 at a second connection. The second ladder inductor 812 is coupled at a first connection to the first ladder inductor 810, sixth resonator 126, seventh resonator 128, and eighth resonator 130, and at a second connection to the third node 106 and the eighth resonator 130. The third ladder inductor 814 is coupled to the fifth resonator 124 at a first connection and an equipotential node at a second connection. The fourth ladder inductor 816 is coupled to the seventh resonator 128 at a first connection and to an equipotential node at a second connection. The impedance matching network 818 is coupled to the third node 106 at a first connection and to the switching device 820 at a second connection. The switching device 820 is coupled to the impedance matching network 818 at a first connection and to the third single-ended port 822 at a second connection. The third single-ended port 822 is coupled to the switching device 820 at a first connection and to an equipotential node at a second connection. The fourth antenna port 824 is coupled to the third node 106 at a first connection and to an equipotential node at a second connection. Nodes 102 and 104 may form the differential inputs to an LNA in the manner shown in FIG. 5. The first and second differential ports 802 and 804 may each have an impedance of approximately 35 Ohms, the third single-ended port 822 may have an impedance of approximately 50 Ohms, and the antenna port 824 may have an impedance of approximately 60 Ohms at frequencies within the n77 band. In the configuration shown in FIG. 8, the filter 800 acts as a single-ended to differential hybrid lattice-ladder filter operating in a common mode.

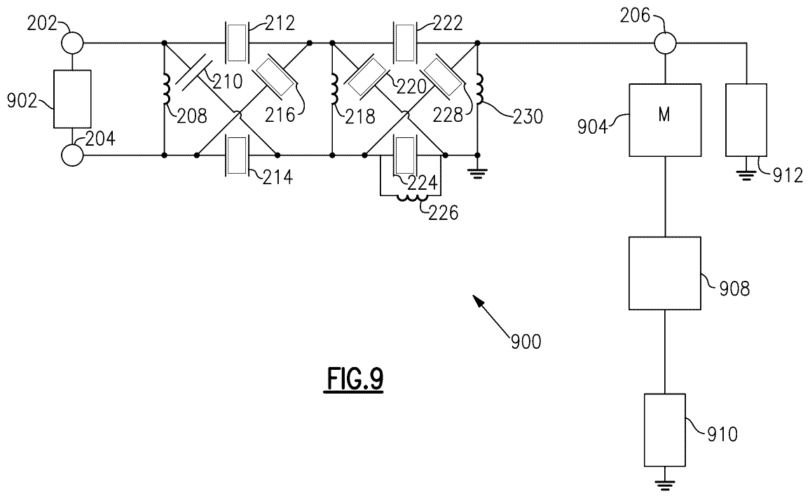

FIG. 9 illustrates a modified dual lattice filter 900 (“dual lattice filter 900”) according to an example.

The dual lattice filter 900 includes the lattice topology 200 of FIG. 2 as well as a first differential port 902, an impedance matching network 904, a switching device 908, a second single-ended port910, and a third antenna port 910.

The first differential port 902 is coupled to the first node 202 at a first connection and to the second node 204 at a second connection. The impedance matching network 904 is coupled to the third node 206 at a first connection and to the switching device 908 at a second connection. The switching device 908 is coupled to the impedance matching network 904 at a first connection and to the second single-ended port 910 at a second connection. The second single-ended port 910 is coupled to the switching device 908 at a first connection and to an equipotential node at a second connection. The third antenna port 912 is coupled to the third node 206 at a first connection and to an equipotential node at a second connection. The first differential port 902 may have an impedance of approximately 70 Ohms, the second single-ended port 910 may have an impedance of approximately 50 Ohms, and the antenna port 912 may have an impedance of approximately 50 Ohms at frequencies within the n77 band. In the configuration shown in FIG. 9, the filter 900 acts as a single-ended to differential dual lattice filter operating in a differential mode.

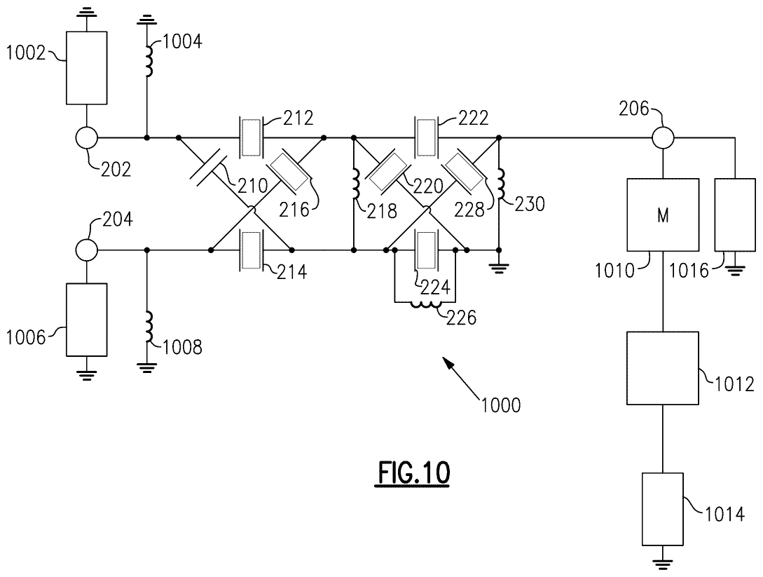

FIG. 10 illustrates a modified differential dual lattice filter 1000 (“differential dual lattice filter”) according to an example.

The differential dual lattice filter 1000 includes the lattice topology 200 of FIG. 2, although the first inductor 208 has been removed. The differential dual lattice filter 1000 also includes a first differential port 1002, a first differential inductor 1004, a second differential port 1006, a second differential inductor 1008, an impedance matching network 1010, a switching device 1012, a third single-ended port 1014, and a fourth antenna port 1016.

The first differential port 1002 is coupled at a first connection to an equipotential node and at a second connection to the first node 202. The first differential inductor 1004 is coupled to an equipotential node at a first connection and to the first node 202 at a second connection. The first resonator 212 and capacitor 210 are coupled to the first node 202 at a first connection as well. The second differential port 1006 is coupled to an equipotential node at a first connection and to the second node 204 at a second connection. The second differential inductor 1008 is coupled to an equipotential node at a first connection and to the second node 204 at a second connection. The second resonator 214 and third resonator 216 are coupled at a first connection to the second node 204. The impedance matching network 1010 is coupled to the third node 206 at a first connection and to the switching device 1012 at a second connection. The switching device 1012 is coupled to the impedance matching network 1010 at a first connection and to the third single-ended port 1014 at a second connection. The third single-ended port 1014 is coupled to the switching device 1012 at a first connection and to an equipotential node at a second connection. The fourth antenna port 1016 is coupled to the third node 206 at a first connection and to an equipotential node at a second connection. The first and second differential ports 1002 and 1006 may each have an impedance of approximately 35 Ohms, the third single-ended port 1014 may have an impedance of approximately 50 Ohms, and the antenna port 1016 may have an impedance of approximately 50 Ohms at frequencies within the n77 band. In the configuration shown in FIG. 10, the filter 1000 acts as a single-ended to differential dual lattice filter operating in a common mode.

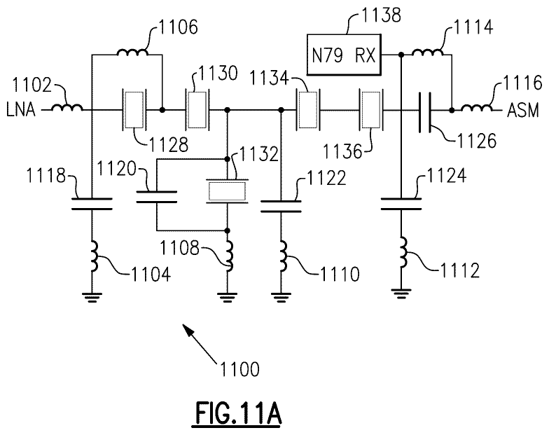

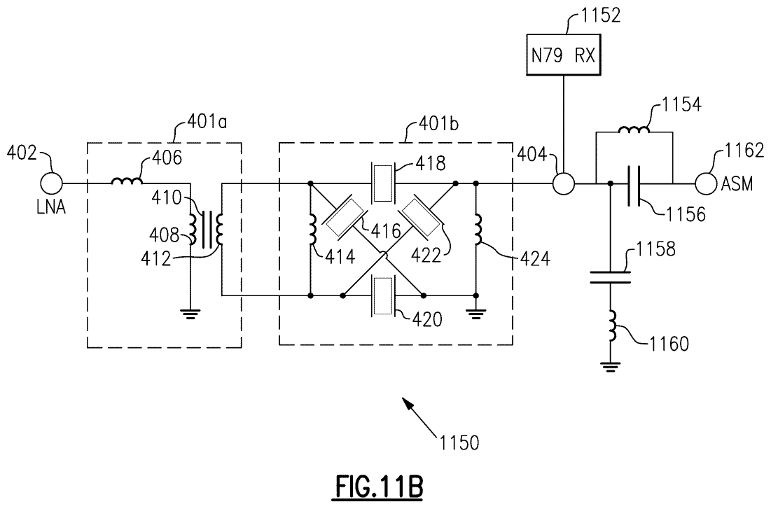

FIG. 11A illustrates a ladder filter 1100 according to an example. The ladder filter 1100 includes a first inductor 1102, a second inductor 1104, a third inductor 1106, a fourth inductor 1108, a fifth inductor 1110, a sixth inductor 1112, a seventh inductor 1114, an eighth inductor 1116, a first capacitor 1118, a second capacitor 1120, a third capacitor 1122, a fourth capacitor 1124, a fifth capacitor 1126, a first resonator 1128, a second resonator 1130, a third resonator 1132, a fourth resonator 1134, a fifth resonator 1136, and an Rx node 1138.

The first inductor 1102 may be coupled to an LNA at a first connection, and is coupled to the first capacitor 1118, first resonator 1128, and third inductor 1106 at a second connection. The second inductor 1104 is coupled to an equipotential node at a first connection and to the first capacitor 1118 at a second connection. The third inductor 1106 is coupled to the first inductor 1102, the first resonator 1128, and the first capacitor 1118 at a first connection, and to the first resonator 1128 and second resonator 1130 at a second connection. The fourth inductor 1108 is coupled to the second capacitor 1120 and the third resonator 1132 at a first connection and to an equipotential node at a second connection. The fifth inductor 1110 is coupled to the third capacitor 1122 at a first connection and to an equipotential node at a second connection. The sixth inductor 1112 is coupled to the fourth capacitor 1124 at a first connection and to an equipotential node at a second connection. The seventh inductor 1114 is coupled to the Rx node 1138, fifth resonator 1136, fourth capacitor 1124, and fifth capacitor 1126 at a first connection, and to the fifth capacitor 1126 and eighth inductor 1116 at aa second connection. The eighth inductor 1116 is coupled to the fifth capacitor 1126 and seventh inductor 1114 at a first connection and may be coupled to another circuit element, such as an Antenna Switch Module (ASM)) at a second connection.

The first capacitor 1118 is coupled to the first inductor 1102, third inductor 1106, and first resonator 1128 at a first connection and to the second inductor 1104 at a second connection. The second capacitor 1120 is coupled to the second resonator 1130, third resonator 1132, fourth resonator 1134, and third capacitor 1122 at a first connection and to the third resonator 1132 and fourth inductor 1108 at a second connection. The third capacitor 1122 is coupled to the fifth inductor 1110 at a first connection and to the second resonator 1130, third resonator 1132, fourth resonator 1134, and second capacitor 1120 at a second connection. The fourth capacitor 1124 is coupled to the sixth inductor 1112 at a first connection and to the fifth resonator 1136, fifth capacitor 1126, seventh inductor 1114, and Rx node 1138 at a second connection. The fifth capacitor 1126 is coupled to the first capacitor 1124, fifth resonator 1136, Rx node 1138, and seventh inductor 1114 at a first connection, and to the seventh inductor 1114 and eighth inductor 1116 at a second connection.

The first resonator 1128 is coupled to the first inductor 1102, third inductor 1106, and first capacitor 1118 at a first connection and to the third inductor 1106 and second resonator 1130 at a second connection. The second resonator 1130 is coupled to the first resonator 1128 and third inductor 1106 at a first connection and to the third resonator 1132, fourth resonator 1134, second capacitor 1120, third capacitor 1122 at a second connection. The third resonator 1132 is coupled to the fourth inductor 1108 and second capacitor 1120 at a first connection and to the second resonator 1130, third resonator 1134, and third capacitor 1122 at a second connection. The fourth resonator 1134 is coupled to the fifth resonator 1136 at a first connection and to the second resonator 1130, third resonator 1132, second capacitor 1120, and third capacitor 122 at a second connection. The fifth resonator 1136 is coupled to the fourth resonator 1134 at a first connection and to the fourth capacitor 1124, fifth capacitor 1126, seventh inductor 1114, and Rx node 1138 at a second connection.

The Rx node 1138 may be configured to receive a signal and provide the signal to the ladder filter 1100. In some examples, the Rx node 1138 may provide and/or receive signals corresponding to the N79 frequency band. The ASM may be connected to receive another frequency band, such as an n77 frequency band signal, for example.

FIG. 11B illustrates an example of a lattice filter 1150 according to an example. The lattice filter 1150 includes the SE topology 400 of FIG. 4. The lattice filter 1150 further includes an Rx node 1152, a first inductor 1154, a first capacitor 1156, a second capacitor 1158, a second inductor 1160, and a third node 1162.

The Rx node 1152 is coupled to the second node 404, the first inductor 1154 is coupled to the second node 404 at a first connection and to the third node 1162 at a second node. The first capacitor 1156 is coupled to the second node 404 at a first connection and to the third node 1162 at a second connection. The second capacitor 1158 is coupled to the second node 404 at a first connection and to the second inductor 1160 at a second connection. The second inductor 1160 is coupled to the second capacitor 1158 at a first connection and to an equipotential node at a second connection.

The Rx node 1152 may be configured to receive a signal and provide that signal to the lattice filter 1150. In some examples, the Rx node 1152 may provide and/or receive signals corresponding to the N79 frequency band. The third node 1162 may be connected to an ASM that may be configured to receive another frequency band, such as an n77 frequency band signal, for example, and meet more stringent IMD requirements while providing a competitive noise factor. For example, the lattice filter 1150 of FIG. 11B includes fewer components than the ladder filter 1100 of FIG. 11A, while providing good band rejection at lowband, midband, and highband frequencies, and a 0.5 dB improvement in insertion loss as compared to the ladder filter 1100 of FIG. 11A.

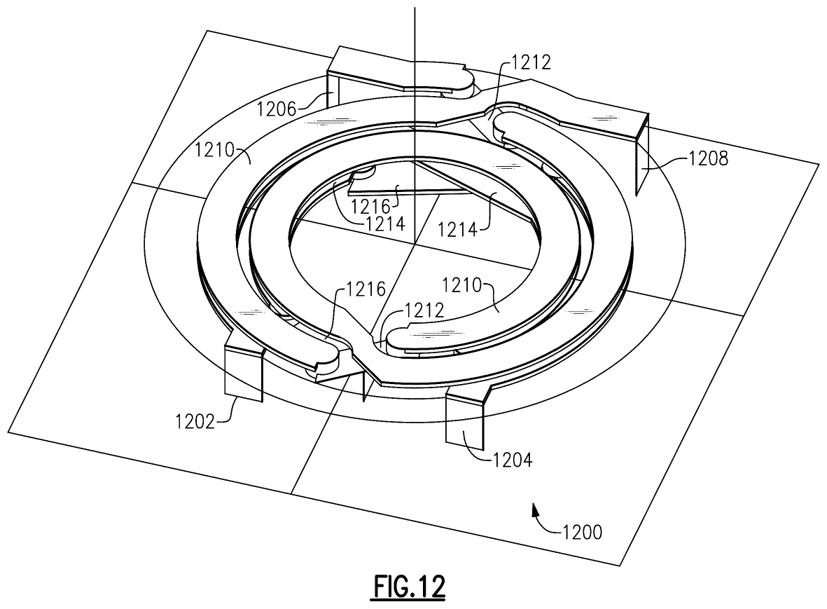

FIG. 12 illustrates a balun transformer 1200 according to an example. The balun transformer 1200 may be one implementation of the second inductor 408, third inductor 412, and/or core 410 of the SE topology 400 shown in FIG. 4.

The balun transformer 1200 includes a first contact 1202, a second contact 1204, a third contact 1206, a fourth contact 1208, a first coil 1210, a first connective element 1212, a second coil 1214, and a second connective element 1216.

The first contact 1202 is coupled to the second coil 1214 at a first connection. The second contact 1202 is coupled to the second coil 1214 at a second connection. The third contact 1206 is coupled to the first coil 1210 at a first connection. The fourth contact 1208 is coupled to the first coil 1210 at a second connection.

Each coil may be divided into discrete sections. Those sections may be coupled together via the connective elements. The first connective element 1212 couples together one or more sections of the first coil 1210. In FIG. 12, the first connective element 1212 comprises two discrete portions connecting three discrete portions of the first coil 1210. The second connective element 1216 couples together one or more sections of the second coil 1214. In FIG. 12, the second connective element 1216 comprises two discrete portions connecting three discrete portions of the second coil 1214.

The nodes may be coupled to other circuit elements. In at least some examples, the first node 1202 may be coupled to a first input (e.g., a positive polarity input), the second node 1204 may be coupled to a second input (e.g., a negative polarity input), the third node 1206 may be coupled to a first output (e.g., an LNA output), and the fourth node 1208 may be coupled to a second output (e.g., an equipotential node output).

In some examples, the balun transformer 1200 may be integrated into the substrate of the chip or circuit, such as the substrate of the circuit the SE topology 400 of FIG. 4 is implemented in.

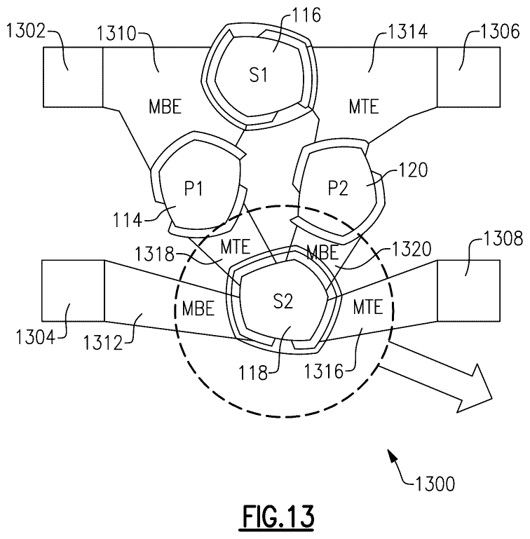

FIG. 13 illustrates an example of a cross-connection 1300 according to an example. The cross-connection 1300 may be used to implement crossed resonators, such as the first resonator 114 and fourth resonator 120 of FIG. 1.

The cross-connection 1300 includes a first node 1302, a second node 1304, a third node 1306, a fourth node 1308, a first connective element 1310, a second connective element 1312, a third connective element 1314, a fourth connective element 1316, a fifth connective element 1318, and a sixth connective element 1320. The cross-connection 1300 also includes the first resonator 114, second resonator 116, third resonator 118, and fourth resonator 120.

The first node 1302 is coupled to the first connective element 1310 and configured to connect to other circuit elements. The second node 1304 is coupled to the second connective element 1312 and configured to connect to other circuit elements. The third node 1306 is coupled to the third connective element 1314 and configured to connect to other circuit elements. The fourth node 1308 is coupled to the fourth connective element 1316. The first resonator 114 is coupled to the first connective element 1310 at a first connection and to the second fifth connective element 1318 at a second connection. The second resonator 116 is coupled to the first connective element 1310 at a first connection and to the third connective element 1314 at a second connection. The third resonator 118 is coupled to the second connective element 1312 at a first connection, the fifth connective element 1318 at a second connection, the sixth connective element 1320 at a third connection, and the fourth connective element 1316 at a fourth connection. The fourth resonator 120 is coupled to the third connective element 1314 at a first connection and to the sixth connective element 1320 at a second connection.

In some examples, the first connective element 1310 is coupled to the metal bottom electrode (MBE) of the first resonator 114 and second resonator 116. In some examples, the second connective element 1312 is coupled to the metal bottom electrode of the third resonator 118. In some examples, the third connective element 1314 is coupled to the metal top electrode (MTE) of the second resonator 116 and fourth resonator 120. In some examples, the fourth connective element 1316 is coupled to the metal top electrode of the third resonator 118. In some examples, the fifth connective element 1318 is coupled to the metal top electrode of the first resonator 114 and third resonator 118. In some examples, the sixth connective element 1320 is coupled to the third resonator 118 and fourth resonator 120. By coupling the electrodes in this way, bridges may be formed wherein current may flow from the first node 1302 to the fourth node 1308 through the first resonator 114 and then along the first fifth connective element 1318 and fourth connective element 1316 without necessarily passing through the third resonator 118.

Likewise, current may pass from the second node 1304 to the third node 1306 through the second connective element 1312, sixth connective element 1320, fourth resonator 120, and third connective element 1314 without passing necessarily passing through the third resonator 118.

Various controllers may execute various operations discussed above. Using data stored in associated memory and/or storage, the controller may also executes one or more instructions stored on one or more non-transitory computer-readable media, which the controller may include and/or be coupled to, that may result in manipulated data. In some examples, the controller may include one or more processors or other types of controllers. In one example, the controller is or includes at least one processor. In another example, the controller performs at least a portion of the operations discussed above using an application-specific integrated circuit tailored to perform particular operations in addition to, or in lieu of, a general-purpose processor. As illustrated by these examples, examples in accordance with the present disclosure may perform the operations described herein using many specific combinations of hardware and software and the disclosure is not limited to any particular combination of hardware and software components. Examples of the disclosure may include a computer-program product configured to execute methods, processes, and/or operations discussed above. The computer-program product may be, or include, one or more controllers and/or processors configured to execute instructions to perform methods, processes, and/or operations discussed above.

Having thus described several aspects of at least one embodiment, it is to be appreciated various alterations, modifications, and improvements will readily occur to those skilled in the art. Such alterations, modifications, and improvements are intended to be part of, and within the spirit and scope of, this disclosure. Accordingly, the foregoing description and drawings are by way of example only.

1. A circuit comprising:
a first output;
a second output;
an input;
a lattice filter stage; and
a ladder filter stage coupled to the input and to the lattice filter stage, the lattice filter stage including a first resonator coupled to the first output and to the ladder filter stage, a second resonator coupled to the second output and to the ladder filter stage, the ladder stage including a third resonator coupled to the input and a fourth resonator coupled to a ground connection.

2. The circuit of claim 1 wherein the lattice filter stage further incudes a fifth resonator coupled between the first output and the ground connection and a sixth resonator coupled between the second output and the third resonator.

3. The circuit of claim 2 wherein the ladder filter stage further includes a seventh resonator coupled between the first resonator and the third resonator, an eighth resonator coupled between the first and seventh resonators and the ground connection, and wherein the fourth resonator is coupled between the seventh and third resonators and the ground connection.

4. The circuit of claim 3 wherein each of the fourth and eighth resonators is coupled to the ground connection through a respective inductor.

5. The circuit of claim 3 wherein the ladder filter stage further includes first and second inductors coupled in parallel with the seventh and third resonators, respectively.

6. The circuit of claim 1 wherein the input is coupled to an antenna and to a first port via a matching impedance.

7. The circuit of claim 1 wherein the first output is coupled to a first differential input port of a low noise amplifier and wherein the second output is coupled to a second differential input of the low noise amplifier.

8. A circuit comprising:
a first output;
a second output;
an input;
a first lattice filter stage; and
a second lattice filter stage, the first lattice filter stage including a first resonator coupled to the first output, a capacitor coupled to the first output, and a second resonator coupled to the second output, the second lattice filter stage including a third resonator coupled to the input.

9. The circuit of claim 8 wherein the first lattice filter further includes a fourth resonator coupled between the second output and the third resonator.

10. The circuit of claim 9 wherein the second lattice filter further includes a fifth resonator coupled between the first and third resonators and a ground connection and a sixth resonator coupled between the second resonator and the input.

11. The circuit of claim 10 wherein the second lattice filter further includes a seventh resonator coupled between the second resonator and the ground connection.

12. The circuit of claim 11 wherein the second lattice filter further includes a first inductor coupled between the input and the ground connection.

13. The circuit of claim 12 further comprising a second inductor coupled between the first and third resonators and the second and seventh resonators, and a third inductor coupled between the first and second outputs.

14. The circuit of claim 13 further comprising a fourth inductor coupled in parallel with the seventh resonator.

15. The circuit of claim 13 further comprising a balun, wherein the balun includes the third inductor, a fourth inductor and a core, a first terminal of the fourth inductor being coupled to a single input low noise amplifier and a second terminal of the fourth inductor being coupled to the ground connection.

16. The circuit of claim 8 wherein the input is coupled to an antenna and to a first port via a matching impedance.

17. The circuit of claim 8 wherein the first output is configured to be coupled to a first differential input port of a low noise amplifier and wherein the second output is configured to be coupled to a second differential input of the low noise amplifier.

18. A circuit comprising:
a first output;
a second output;
an input;
a first lattice filter stage coupled to the first input and including a first resonator;
a second lattice filter stage coupled to the second input and including a second resonator;
a first coil coupled to the first lattice filter stage;
a second coil coupled to the second lattice filter stage; and
a third coil coupled to the output and electromagnetically coupled to at least one of the first coil or the second coil.

19. The circuit of claim 18 wherein the first output is configured to be coupled to a first differential input of a low noise amplifier and wherein the second output is configured to be coupled to a second differential input of the low noise amplifier.

20. The circuit of claim 18 wherein the input is configured to be coupled to an antenna.
